(19) United States
(12) Patent Application Publication
(10) Pub. No.: US 2023/0318272 A1
(43) Pub. Date: Oct. 5, 2023

(54) WIRE HARNESS UNIT

(71) Applicant: SUMITOMO WIRING SYSTEMS, LTD., Yokkaichi-shi, Mie (JP)

(72) Inventor: Takeo MARUCHI, Yokkaichi-shi (JP)

(73) Assignee: SUMITOMO WIRING SYSTEMS, LTD., Yokkaichi-shi, Mie (JP)

(21) Appl. No.: 18/020,862

(22) PCT Filed: Aug. 4, 2021
(86) PCT No.: PCT/JP2021/028873

§ 371 Date: Feb. 10, 2023

(30) Foreign Application Priority Data
Aug. 26, 2020 (JP) 2020-142643

(51) Int. Cl. H02G 3/03; H05K 9/00; H02G 3/22; B60R 16/02

(52) U.S. Cl. CPC H02G 3/03; H05K 9/0098; H02G 3/22; B60R 16/0222

(57) ABSTRACT

A wire harness unit including: a plurality of conductive paths for conducting electricity between in-vehicle devices, wherein: the plurality of conductive paths include a first conductive path and a second conductive path parallel with the first conductive path, the first conductive path includes a first inner insulating layer formed in a hollow tube shape, and a first tubular conductor that covers an outer circumferential surface of the first inner insulating layer, and the second conductive path includes a second inner insulating layer formed in a hollow tube shape, and a second tubular conductor that covers an outer circumferential surface of the second inner insulating layer.

### TECHNICAL FIELD

The present disclosure relates to a wire harness unit.

### BACKGROUND ART

Conventionally, wire harnesses installed in vehicles such as hybrid cars and electric cars electrically connect a plurality of electrical devices to each other. Also, in electric cars, vehicles and ground facilities are connected to each other by a wire harness, and a power storage device installed in the vehicle is charged by the ground facility. As a result of a voltage supplied through the wire harness being high, the amount of heat generated by the wire harness is increased. For this reason, configurations for cooling wire harnesses have been proposed.

For example, Patent Document 1 discloses a wire harness provided with a coated wire, an inner tube that covers the coated wire, and an outer tube that covers the inner tube with a predetermined space therebetween, in which a circulation path for a coolant is formed between the inner tube and the outer tube. The circulation path is formed by inner and outer tubes that are separate from the coated wire, and the coated wire is disposed radially inward of the circulation path.

### CITATION LIST

### Patent Documents

Patent Document 1: JP 2019-115253A

### SUMMARY OF INVENTION

### Problem to be Solved

Incidentally, in the wire harness disclosed in Patent Document 1, the circulation path (a path along which the coolant flows) is disposed outside the coated wire, and thus the coolant is far from the central portion of the coated wire, which is the heat source. Accordingly, there is room for improvement in terms of cooling efficiency of the coated wire.

An object of the present disclosure is to provide a wire harness unit capable of improving cooling efficiency.

### Solution to Problem

A wire harness unit that is an aspect of the present disclosure includes a plurality of conductive paths for conducting electricity between in-vehicle devices, and a cooling portion for cooling the plurality of conductive paths, the plurality of conductive paths include a first conductive path and a second conductive path parallel with the first conductive path, the first conductive path includes a first inner insulating layer formed in a hollow tube shape, and a first tubular conductor that covers an outer circumferential surface of the first inner insulating layer, the second conductive path includes a second inner insulating layer formed in a hollow tube shape, and a second tubular conductor that covers an outer circumferential surface of the second inner insulating layer, and the cooling portion includes a first cooling tube constituted by the first inner insulating layer through which a coolant is able to flow, a second cooling tube constituted by the second inner insulating layer through which a coolant is able to flow, and a turnback tube that links the first cooling tube and the second cooling tube.

### Advantageous Effects of Invention

According to a wire harness unit that is an aspect of the present disclosure, cooling efficiency can be improved.

### BRIEF DESCRIPTION OF DRAWINGS

FIG. 1 is a schematic diagram showing a vehicle in which a wire harness unit according to an embodiment is routed.

FIG. 2 is a schematic diagram of the wire harness unit.

FIG. 3 is a partial cross sectional view showing an overview of the wire harness unit.

FIG. 4 is a cross sectional view of the wire harness unit.

FIG. 5 is a diagram illustrating connection between a tubular conductor and a terminal.

FIG. 6 is a schematic diagram showing a portion of the wire harness unit.

FIG. 7 is a partial cross-sectional view showing an overview of a wire harness unit according to a variation.

FIG. 8 is a schematic diagram showing a portion of the wire harness unit according to the variation.

FIG. 9 is a schematic diagram showing a portion of a wire harness unit according to a variation.

### DESCRIPTION OF EMBODIMENTS

### Description of Embodiments of Disclosure

First, aspects of the present disclosure will be listed and described.

[1] A wire harness unit according to the present includes a plurality of conductive paths for conducting electricity between in-vehicle devices, and a cooling portion for cooling the plurality of conductive paths, the plurality of conductive paths include a first conductive path and a second conductive path that is parallel with the first conductive path, the first conductive path includes a first inner insulating layer formed in a hollow tube shape, and a first tubular conductor that covers an outer circumferential surface of the first inner insulating layer, the second conductive path includes a second inner insulating layer formed in a hollow tube shape, and a second tubular conductor that covers an outer circumferential surface of the second inner insulating layer, and the cooling portion includes a first cooling tube constituted by the first inner insulating layer through which a coolant is able to flow, a second cooling tube constituted by the second inner insulating layer through which a coolant is able to flow, and a turnback tube that links the first cooling tube and the second cooling tube.

According to this configuration, a coolant can flow through the first cooling tube constituted by the first inner insulating layer that is covered by the first tubular conductor, and the second cooling tube constituted by the second inner insulating layer that is covered by the second tubular conductor. For this reason, the first tubular conductor and the second tubular conductor can be cooled from the inside, thereby making it possible to improve cooling efficiency. Moreover, since the cooling portion includes the turnback tube that links the first cooling tube constituted by the first inner insulating layer and the second cooling tube constituted by the second inner insulating layer, it is possible to reduce the number of inlets and outlets for the coolant and simplify the structure for connection to a pump, for example, compared with a case where the cooling tube does not include the turnback tube.

[2] It is preferable that the number of conductive paths included in the plurality of conductive paths is an even number.

According to this configuration, since the number of conductive paths included in the plurality of conductive paths is an even number, the inlet and the outlet for the coolant can be easily positioned close to each other. That is to say, a situation is avoided where the positions of the inlet and the outlet for the coolant are spaced far apart from each other when, for example, the number of conductive paths is three, which is an odd number, and the cooling portion further includes a third cooling tube constituted by a third inner insulating layer of a third conductive path, and a turnback tube that links the second cooling tube and the third cooling tube. Thus, it is possible to easily set the positions of the inlet and the outlet for the coolant close to each other, and to reduce a routing space and the like for connection to a pump, for example.

[3] It is preferable that the wire harness unit further includes an exterior member for covering the conductive paths, the exterior member includes a tubular exterior member and a grommet that is connected to an end portion of the tubular exterior member, and the turnback tube is disposed inside the grommet.

According to this configuration, since the turnback tube is disposed inside the grommet, it is possible to easily house the turnback tube, for example. Even in a case where, for example, the turnback tube is configured such that it cannot be sharply bent, and a large space is required, such a case can be easily addressed without increasing the entire size of the tubular exterior member. Moreover, for example, if the grommet is shaped such that the size thereof increases toward a member that is connected to the grommet, the turnback tube can be easily housed in a large space.

[4] It is preferable that the turnback tube is separate from the first cooling tube and the second cooling tube.

According to this configuration, since the turnback tube is separate from the first cooling tube and the second cooling tube, it is easy to manufacture the wire harness unit compared with a case where the turnback tube is integrated with the first cooling tube and the second cooling tube, for example.

[5] It is preferable that the turnback tube is integrated with the first cooling tube and the second cooling tube.

According to this configuration, since the turnback tube is integrated with the first cooling tube and the second cooling tube, the number of components is small compared with a case where the turnback tube is separate from the first cooling tube and the second cooling tube, for example.

[6] It is preferable that the first tubular conductor is a first braided member formed by braiding metal strands, and the second tubular conductor is a second braided member formed by braiding metal strands.

According to this configuration, the first tubular conductor is a first braided member formed by braiding metal strands, the second tubular conductor is a second braided member formed by braiding metal strands, both of the first tubular conductor and the second tubular conductor are flexible, and thus, dimensional tolerance of the conductive paths can be absorbed.

Further, this configuration is a counter measure against swinging generated while a vehicle is travelling.

[7] It is preferable that the wire harness unit further includes an electromagnetic shield member for covering the conductive paths, the electromagnetic shield member is a shielding braided member formed by braiding metal strands, the first inner insulating layer and the second inner insulating layer each include an exposed insulating portion that is exposed from the first tubular conductor or the second tubular conductor, and the exposed insulating portion extends through the shielding braided member.

According to this configuration, both the shielding properties for suppressing electromagnetic noise radiation from the conductive paths and an improvement in the ease of assembly of the cooling portion can be achieved.

[8] It is preferable that the first conductive path and the second conductive path each include a terminal and an outer insulating layer that covers an outer circumferential surface of the first tubular conductor or the second tubular conductor, the first tubular conductor and the second tubular conductor include an exposed conductor portion exposed from the outer insulating layer, the exposed conductor portion is electrically connected to the terminal, and the exposed conductor portion is covered by the electromagnetic shield member.

According to this configuration, both the shielding properties for suppressing electromagnetic noise radiation from the conductive paths and an improvement in the ease of assembly of the cooling portion can be achieved.

[9] It is preferable that the wire harness unit further includes a coating member for covering the exposed conductor portion.

According to this configuration, it is possible to prevent the exposed conductor portions of the first tubular conductor and the second tubular conductor from coming into contact with the electromagnetic shield member.

[10] It is preferable that the wire harness unit further includes an exterior member for covering the conductive paths, the exterior member includes a tubular exterior member and a grommet connected to an end portion of the tubular exterior member, and the first inner insulating layer and the second inner insulating layer extend through the grommet.

According to this configuration, since the first inner insulating layer that is the first cooling tube, and the second inner insulating layer that is the second cooling tube extend through the grommet and are led out to the outside, a decrease in the water blocking properties of the wire harness unit can be suppressed.

### Description of Embodiments of Disclosure

Specific examples of a wire harness unit according to the present disclosure will be described below with reference to the drawings. Note that, in the drawings, parts of the configurations may be shown in an exaggerated or simplified manner for convenience of description. Moreover, dimensional ratios of various portions may be different from actual dimensional ratios.

“Parallel” and “orthogonal” in the present specification include not only being exactly parallel and orthogonal but also approximately parallel and orthogonal within a range in which the operation and effects of the present embodiment can be achieved. The present invention is not limited to the embodiments disclosed herein, but is defined by the claims, and intended to include all modifications within the meaning and the scope equivalent thereof.

### Overview Configuration of Wire Harness Unit 10

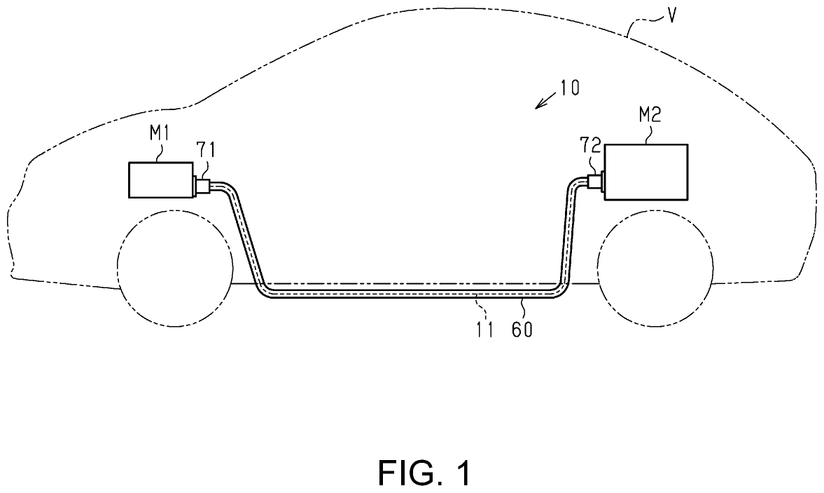

A wire harness unit 10 shown in FIG. 1 electrically connects two in-vehicle devices installed in a vehicle V. The vehicle V is, for example, a hybrid car, an electric car, or the like. The wire harness unit 10 includes conductive paths 11 for electrically connecting an in-vehicle device M1 and an in-vehicle device M2, and an exterior member 60 for covering the conductive paths 11. The conductive paths 11 are routed, for example, from the in-vehicle device M1 to the in-vehicle device M2 so that portions thereof in a lengthwise direction pass under the floor of the vehicle V. With regard to examples of the in-vehicle device M1 and the in-vehicle device M2, the in-vehicle device M1 is an inverter installed toward the front side of the vehicle V, and the in-vehicle device M2 is a high-voltage battery installed on the rear side of the vehicle V relative to the in-vehicle device M1. The in-vehicle device M1 serving as an inverter is connected to a motor (not shown) for driving the wheels serving as a motive power source for causing the vehicle to travel, for example. The inverter generates AC power from DC power from the high-voltage battery, and supplies the AC power to the motor. The in-vehicle device M2, which is a high-voltage battery, is a battery capable of supplying a voltage of at least 100 V, for example. In other words, the conductive paths 11 of the present embodiment constitute a high-voltage circuit that enables high-voltage exchange between the high-voltage battery and the inverter.

### Detailed Configuration of Wire Harness Unit 10

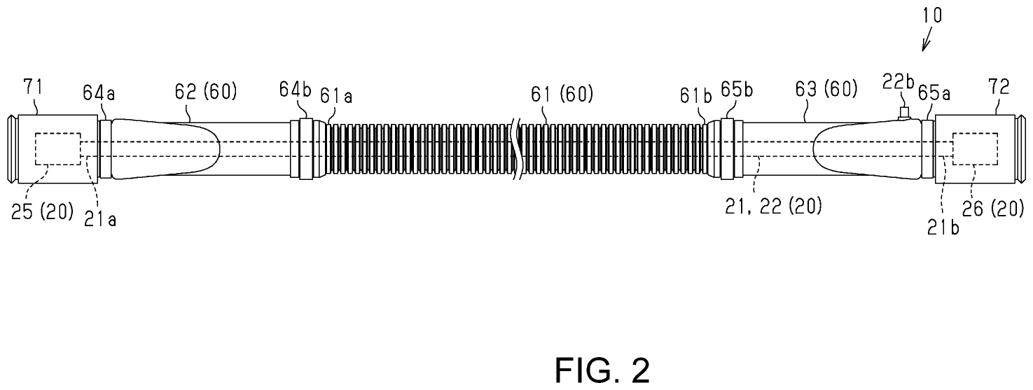

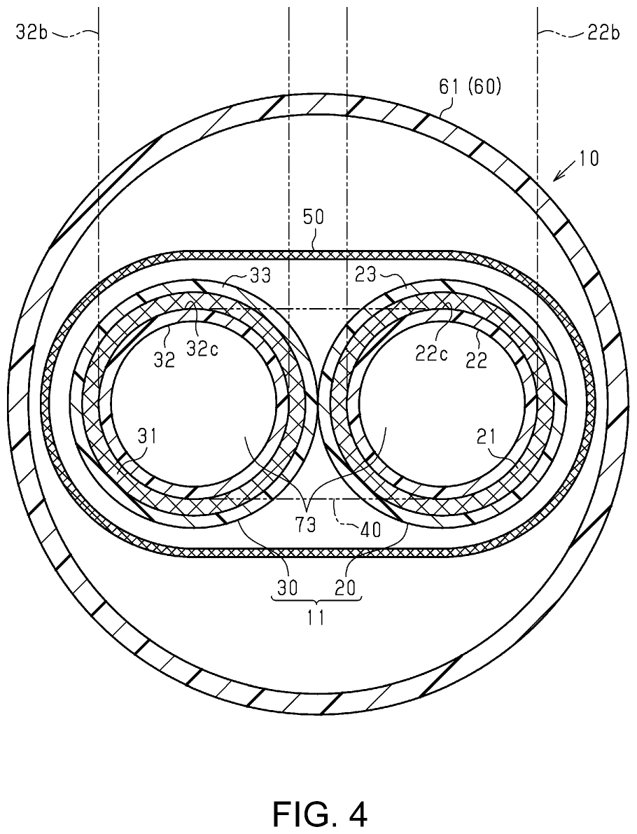

As shown in FIGS. 2, 3, and 4, the wire harness unit 10 includes a plurality of conductive paths 11, a turnback tube 40, an electromagnetic shield member 50, the exterior member 60, and connectors 71 and 72. As shown in FIGS. 4 and 6, the plurality of conductive paths 11 include a first conductive path 20 and a second conductive path 30 that is parallel with the first conductive path 20.

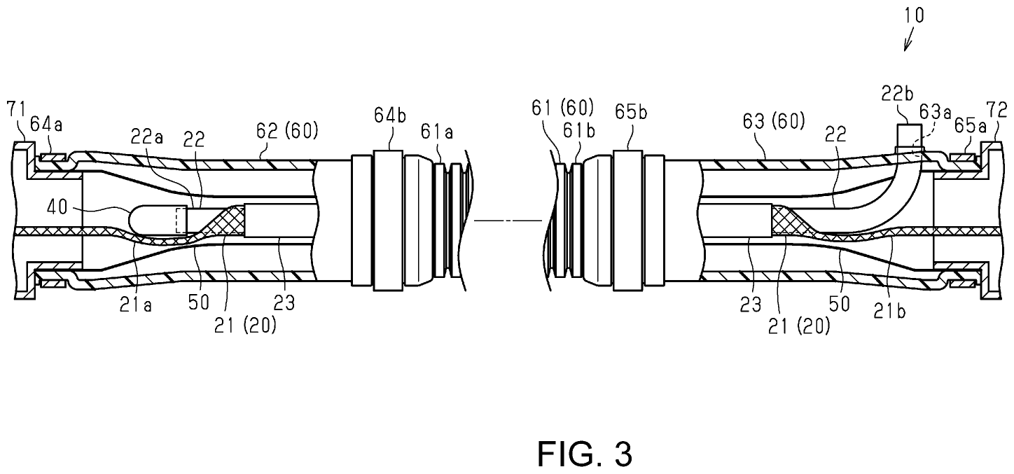

As shown in FIGS. 3 to 6, the first conductive path 20 includes a first tubular conductor 21, a first inner insulating layer 22, an outer insulating layer 23, and terminals 25 and 26.

The first tubular conductor 21 is conductive and has a hollow structure. The first tubular conductor 21 is a first braided member formed by braiding metal strands, for example. A plating layer of tin or the like may be formed on the surfaces of the metal strands. The material for the first tubular conductor 21 is a metal material such as a copper-based material or an aluminum-based material. The first tubular conductor 21 is formed in a shape conforming to a routing path of the wire harness unit 10 shown in FIG. 1. The first tubular conductor 21 is bent using a pipe bender (in other words, a pipe bending device).

FIG. 4 is a cross-sectional view of the wire harness unit 10 taken along a plane orthogonal to the lengthwise direction of the wire harness unit 10. In FIG. 4, the lengthwise direction of the first tubular conductor 21 is the front-back direction of the sheet plane of FIG. 4. The cross-sectional shape of the first tubular conductor 21 taken along a plane that is vertical to the lengthwise direction of the first tubular conductor 21, that is, a direction in which the first tubular conductor 21 extends and that is the axial direction of the first tubular conductor 21 (i.e., a lateral cross-sectional shape) is annular, for example. Note that the cross sectional shape of the first tubular conductor 21 can be any shape. Also, with respect to the cross sectional shape of the first tubular conductor 21, the shapes of the outer circumference and the inner circumference may be different from each other. Also, cross sectional shapes of the first tubular conductor 21 in the lengthwise direction may be different from each other.

The first inner insulating layer 22 has a hollow structure, and is flexible. Also, the first inner insulating layer 22 is insulative. The outer circumferential surface of the first inner insulating layer 22 is covered by the first tubular conductor 21. The first inner insulating layer 22 is constituted by an insulating material such as a synthetic resin. Examples of the material for the first inner insulating layer 22 include a silicone resin, a synthetic resin whose main component is a polyolefin resin such as cross-linked polyethylene or cross-linked polypropylene, and the like. A single kind of material, or two or more kinds of materials can be used in combination as appropriate, for the first inner insulating layer 22. The first inner insulating layer 22 can be formed by performing extrusion molding (extrusion coating) on the first tubular conductor 21, for example.

The outer insulating layer 23 covers the entirety of the outer circumferential surface of the first tubular conductor 21 in the circumferential direction, for example. The outer insulating layer 23 is flexible. Also, the outer insulating layer 23 is insulative. The outer insulating layer 23 is constituted by an insulating material such as a synthetic resin. Examples of the material for the outer insulating layer 23 include a silicone resin, a synthetic resin whose main component is a polyolefin resin such as cross-linked polyethylene or cross-linked polypropylene, and the like. A single kind of material, or two or more kinds of materials can be used in combination as appropriate, for the outer insulating layer 23. The outer insulating layer 23 can be formed by performing extrusion molding (extrusion coating) on the first tubular conductor 21, for example.

As shown in FIG. 3, the first inner insulating layer 22 includes exposed insulating portions 22a and 22b exposed from the first tubular conductor 21, at the two ends in the lengthwise direction of the first inner insulating layer 22.

As shown in FIG. 3, the first tubular conductor 21 includes exposed conductor portions 21a and 21b that are exposed from the outer insulating layer 23, at the two ends in the lengthwise direction of the first tubular conductor 21.

As shown in FIG. 3, the exposed conductor portion 21a extends to the connector 71. The exposed conductor portion 21b extends to the connector 72.

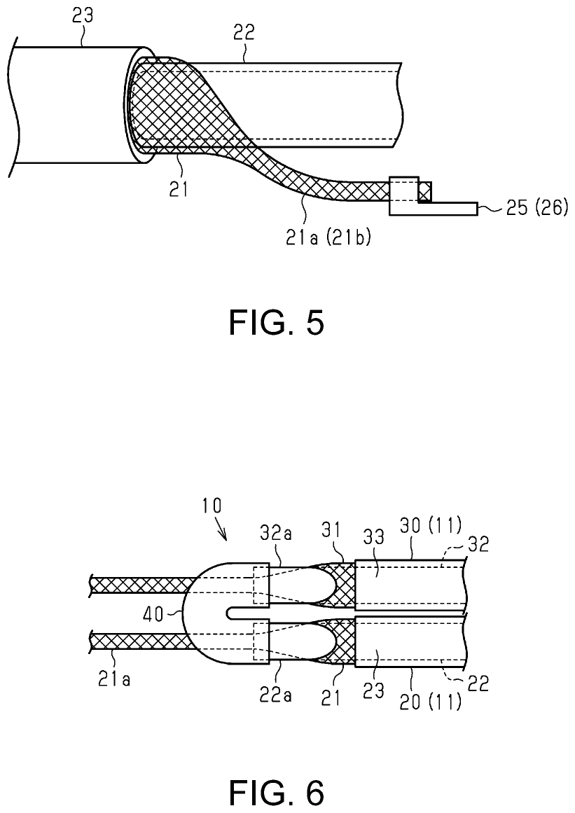

FIG. 5 is an illustrative diagram showing connection between the first tubular conductor and the terminals. Note that, in FIG. 5, the members of the first conductive path 20 shown on the left side of FIGS. 2 and 3 are indicated by reference signs without parentheses, and the members shown on the right side of FIGS. 2 and 3 are indicated by reference signs in parentheses.

The terminal 25 is held by the connector 71 shown in FIGS. 1 and 2, and connected to the in-vehicle device M1. The terminal 25 is connected to a leading end of the exposed conductor portion 21a of the first tubular conductor 21. For example, the terminal 25 includes a pair of crimping pieces, with which the terminal 25 is crimped to the leading end of the exposed conductor portion 21a. The terminal 26 is held by the connector 72 shown in FIGS. 1 and 2, and connected to the in-vehicle device M2. The terminal 26 is connected to a leading end of the exposed conductor portion 21b of the first tubular conductor 21. For example, the terminal 26 includes a pair of crimping pieces, with which the terminal 26 is crimped to the leading end of the exposed conductor portion 21b.

In addition, the second conductive path 30 includes a second tubular conductor 31, a second inner insulating layer 32, an outer insulating layer 33, and terminals 25 and 26. As shown in FIGS. 4 and 6, the second conductive path 30 is parallel with the first conductive path 20. The second conductive path 30 is configured in a similar manner to the first conductive path 20, and, for example, the second tubular conductor 31 is a second braided member formed by braiding metal strands similarly to the first tubular conductor 21, for example, and is a component having the same model number as the first tubular conductor 21. Also, the second inner insulating layer 32 is configured in a similar manner to the first inner insulating layer 22, and includes exposed insulating portions 32a and 32b that are exposed from the second tubular conductor 31, at the two ends in the lengthwise direction of the second inner insulating layer 32. In this manner, similar names and reference numerals are given to the constituent components of the second conductive path 30 that are similar to the constituent components of the first conductive path 20, and a detailed description thereof is omitted.

The first inner insulating layer 22 constitutes the first cooling tube through which a coolant 73 can flow. The second inner insulating layer 32 constitutes the second cooling tube through which the coolant 73 can flow. The turnback tube 40 links the first inner insulating layer 22 constituting the first cooling tube and the second inner insulating layer 32 constituting the second cooling tube. Specifically, as shown in FIG. 6, the turnback tube 40 is formed to be folded so as to link an end portion of the exposed insulating portion 22a of the first inner insulating layer 22 and an end portion of the exposed insulating portion 32a of the second inner insulating layer 32. The material for the turnback tube 40 is a flexible resin material such as PP (polypropylene), PVC (polyvinyl chloride), or cross-linked PE (polyethylene resin).

The first inner insulating layer 22, the second inner insulating layer 32, and the turnback tube 40 constitute a cooling portion, and the coolant 73 is supplied to the inside of the first inner insulating layer 22, the second inner insulating layer 32, and the turnback tube 40. The coolant 73 may be a liquid such as water and an antifreeze solution, or a fluid such as a gas, or an air-liquid two-phase flow in which a gas and a liquid are mixed. The coolant 73 is supplied by a pump (not shown). The first inner insulating layer 22, the second inner insulating layer 32, and the turnback tube 40 form a part of a circulation path through which the coolant 73 is circulated. The circulation path includes the above-described pump and a heat dissipating portion, for example. The pump pressurizes and feeds the coolant 73 to the first inner insulating layer 22, and pressurizes and feeds the coolant 73 to the second inner insulating layer 32 via the turnback tube 40. The coolant 73 supplied to the first inner insulating layer 22 and the second inner insulating layer 32 performs heat exchange with the first tubular conductor 21 and the second tubular conductor 31 that cover outer circumferential surfaces 22c and 32c of the first inner insulating layer 22 and the second inner insulating layer 32, respectively. The heat dissipating portion cools the coolant 73 by dissipating heat from the coolant 73, of which the temperature has risen due to heat exchange, to the outside. The cooled coolant 73 is pressurized and fed again to the first inner insulating layer 22 by the pump. The first inner insulating layer 22, the second inner insulating layer 32, and the turnback tube 40 constitute a cooling portion for cooling the first tubular conductor 21 and the second tubular conductor 31 using the coolant 73 circulated in this manner.

As shown in FIGS. 3 and 4, the electromagnetic shield member 50 covers two conductive paths 11. The electromagnetic shield member 50 is a shielding braided member formed by braiding metal strands into a tubular shape. The electromagnetic shield member 50 has shielding properties. Also, the electromagnetic shield member 50 is flexible. As shown in FIG. 3, one end of the electromagnetic shield member 50 is connected to the connector 71, and the other end of the electromagnetic shield member 50 is connected to the connector 72. Accordingly, the electromagnetic shield member 50 covers the entire length of the conductive paths 11 that transmit a high voltage. In this manner, the radiation of electromagnetic noise originating from the conductive paths 11 to the outside is suppressed.

The exterior member 60 covers the conductive paths 11 and the electromagnetic shield member 50. The exterior member 60 includes a tubular exterior member 61, and grommets 62 and 63 respectively connected to a first end portion 61a and a second end portion 61b of the tubular exterior member 61.

The tubular exterior member 61 covers portions of the outer circumferences of the first tubular conductor 21 and the second tubular conductor 31 in the lengthwise direction, for example. The tubular exterior member 61 is formed in a tubular shape in which the two ends thereof in the lengthwise direction of the first tubular conductor 21 and the second tubular conductor 31 are open, for example. The tubular exterior member 61 surrounds the entirety of the outer circumferences of the first tubular conductor 21 and the second tubular conductor 31 in the circumferential direction, for example. The tubular exterior member 61 of the present embodiment is formed in a cylindrical shape. The tubular exterior member 61 has a bellows structure in which, for example, annular protruding portions and annular recessed portions are alternately arranged along the axis direction (lengthwise direction) thereof in which the central axial line of the tubular exterior member 61 extends. Examples of the material for the tubular exterior member 61 include a conductive resin material and a non-conductive resin material. Examples of the resin material include a synthetic resin such as polyolefin, polyamide, polyester, and ABS resin. The tubular exterior member 61 of the present embodiment is a corrugated tube made of a synthetic resin.

The grommet 62 is formed in a substantially tubular shape. The grommet 62 is made of rubber, for example. The grommet 62 spans between the connector 71 and the tubular exterior member 61. The grommet 62 is fastened and fixed to the outer surface of the connector 71 by a fastening band 64a so as to be in close contact therewith. Also, the grommet 62 is fastened and fixed to the outer side of the first end portion 61a of the tubular exterior member 61 by a fastening band 64b so as to be in close contact therewith. As shown in FIG. 3, the turnback tube 40 is disposed inside the grommet 62.

The grommet 63 is formed in a substantially tubular shape. The grommet 63 is made of rubber, for example. The grommet 63 spans between the connector 72 and the tubular exterior member 61. The grommet 63 is fastened and fixed to the outer surface of the connector 72 by a fastening band 65a so as to be in close contact therewith. Also, the grommet 63 is fastened and fixed to the outer side of the second end portion 61b of the tubular exterior member 61 by a fastening band 65b so as to be in close contact therewith. Through holes 63a extending through the grommet 63 are formed in the grommet 63. The through holes 63a bring the inside and the outside of the grommet 63 into communication.

In the present embodiment, two through holes 63a are formed in the grommet 63, and the exposed insulating portion 22b of the first inner insulating layer 22 constituting the inlet is inserted into one through hole 63a, and the exposed insulating portion 32b of the second inner insulating layer 32 constituting the outlet is inserted into the other through hole 63a. The through holes 63a are formed so as to be in intimate contact with the outer circumferential surfaces of the exposed insulating portions 22b and 32b that are respectively inserted into the through holes 63a. The exposed insulating portions 22b and 32b of the first inner insulating layer 22 and the second inner insulating layer 32 extend through the electromagnetic shield member 50, and are led from the through holes 63a of the grommet 63 to the outside of the grommet 63.

### Operation

Next, operation of the wire harness unit 10 of the present embodiment will be described.

The wire harness unit 10 includes the conductive paths 11 for conducting electricity between the in-vehicle devices M1 and M2, and a cooling portion for cooling the conductive paths 11. The first conductive path includes the first tubular conductor 21 that is conductive and hollow, and the first inner insulating layer 22 that is covered by the first tubular conductor 21. The second conductive path 30 includes the second tubular conductor 31 that is conductive and hollow, and the second inner insulating layer 32 that is covered by the second tubular conductor 31. The first inner insulating layer 22 is a first cooling tube that constitutes a portion of the cooling portion, and through which a coolant can flow. The second inner insulating layer 32 is a second cooling tube that constitutes a portion of the cooling portion, and through which a coolant can flow. Also, the cooling portion includes the turnback tube 40 that links the first cooling tube and the second cooling tube.

The coolant 73 is supplied to the first inner insulating layer 22. At this time, the coolant 73 flows through the first inner insulating layer 22, the turnback tube 40, and the second inner insulating layer 32 in the stated order. The first inner insulating layer 22 is covered by the first tubular conductor 21. Thus, the first inner insulating layer 22 allows the coolant 73 to flow inside the first tubular conductor 21. For this reason, the first tubular conductor 21 is cooled through heat exchange between the first tubular conductor 21 and the coolant 73 flowing on the inner side of the first inner insulating layer 22. The second inner insulating layer 32 is covered by the second tubular conductor 31. Thus, the second inner insulating layer 32 allows the coolant 73 to flow inside the second tubular conductor 31. For this reason, the second tubular conductor 31 is cooled through heat exchange between the second tubular conductor 31 and the coolant 73 flowing on the inner side of the second inner insulating layer 32. In this manner, the first tubular conductor 21 and the second tubular conductor 31 can be cooled from the inside.

Compared to a braided wire formed by twisting together a plurality of metal strands having the same cross sectional area and a single core wire having a solid structure, the first tubular conductor 21 and the second tubular conductor 31 have a larger outer circumference. In other words, the first tubular conductor 21 and the second tubular conductor 31 have a larger area on the outer circumferential side compared to a braided wire and a single core wire. Accordingly, since heat can be dissipated outward from a larger area, heat dissipation properties can be improved.

The first tubular conductor 21 of the first conductive path 20 is a first braided member formed by braiding metal strands, and includes the exposed conductor portions 21a and 21b that are exposed from the outer insulating layer 23. Leading ends of the exposed conductor portions 21a and 21b are respectively connected to the terminals 25 and 26 fixed to the connectors 71 and 72. The exposed conductor portions 21a and 21b are more flexible than the outer insulating layer 23. Accordingly, dimensional tolerance of the first conductive path 20 can be absorbed. Also, when the vehicle V vibrates, positional deviation between the parts due to the vibration can be absorbed. Accordingly, loads applied to the connectors 71 and 72 and the terminals 25 and 26 can be reduced. In addition, the second conductive path 30 has a configuration similar to the first conductive path 20, and thus has similar operation and effects.

The electromagnetic shield member 50 covers the two conductive paths 11. The electromagnetic shield member 50 is a shielding braided member formed by braiding metal strands into a tubular shape. For this reason, it is possible to suppress electromagnetic noise radiation from the conductive paths 11 to the outside. In addition, for this reason, the exposed insulating portions 22b and 32b can be led out from the electromagnetic shield member 50, at an intermediate portion of the electromagnetic shield member 50. Accordingly, the exposed insulating portions 22b and 32b can be easily led to the outside of the wire harness unit 10, and constituent members for circulating the coolant 73 can be easily connected to the first inner insulating layer 22 and the second inner insulating layer 32.

The wire harness unit 10 includes the exterior member 60 for covering the conductive paths 11. The exterior member 60 includes a tubular exterior member 61, and grommets 62 and 63 respectively connected to a first end portion 61a and a second end portion 61b of the tubular exterior member 61. The exposed insulating portions 22b and 32b of the first inner insulating layer 22 and the second inner insulating layer 32 extend through the grommet 63. In this manner, since the exposed insulating portions 22b and 32b of the first inner insulating layer 22 and the second inner insulating layer 32 extend through the grommet 63 so as to be led to the outside of the wire harness unit 10, degradation of the water blocking properties of the wire harness unit 10 can be suppressed.

As described above, according to the present embodiment, the following effects are achieved.

(1) The coolant 73 can flow inside the first cooling tube constituted by the first inner insulating layer 22 that is covered by the first tubular conductor 21, and the second cooling tube constituted by the second inner insulating layer 32 that is covered by the second tubular conductor 31. For this reason, the first tubular conductor 21 and the second tubular conductor 31 can be cooled from the inside, making it possible to improve cooling efficiency. Moreover, the cooling portion includes the turnback tube 40 that links the first cooling tube constituted by the first inner insulating layer 22 and the second cooling tube constituted by the second inner insulating layer 32, and thus, for example, compared with a case where the cooling portion does not include the turnback tube 40, it is possible to reduce the number of inlets and outlets for the coolant 73, and to simplify the connection structure for connection to a pump.

(2) The plurality of conductive paths 11 include the first conductive path 20 and the second conductive path 30. The number of conductive paths included in the plurality of conductive paths 11 is an even number, and thus the inlet and the outlet for the coolant 73, specifically, the exposed insulating portion 22b of the first inner insulating layer 22 constituting the inlet and the exposed insulating portion 32b of the second inner insulating layer 32 constituting the outlet can be naturally positioned on the same side, and the inlet and the outlet for the coolant can be easily positioned close to each other. That is to say, a situation is avoided where the positions of the inlet and the outlet for the coolant 73 are spaced far apart from each other when, for example, the number of conductive paths 11 is three, which is an odd number, and the cooling portion further includes a third cooling tube constituted by a third inner insulating layer of a third conductive path, and a turnback tube that links the second cooling tube and the third cooling tube. Thus, for example, it is possible to easily set the positions of the exposed insulating portion 22b of the first inner insulating layer 22 constituting the inlet and the exposed insulating portion 32b of the second inner insulating layer 32 constituting the outlet close to each other, and to reduce a routing space and the like for connection to a pump, for example.

(3) The turnback tube 40 is disposed inside the grommet 62, and thus, for example, the turnback tube 40 can be easily housed. Even in a case where, for example, the turnback tube 40 is configured such that it cannot be sharply bent, and a large space is required, such a case can be easily addressed without increasing the entire size of the tubular exterior member 61. Moreover, for example, if the grommet 62 is shaped such that the size thereof increases toward a member that is connected thereto, the turnback tube 40 can be easily housed in a large space.

(4) Since the turnback tube 40 is separate from the first cooling tube constituted by the first inner insulating layer 22 and the second cooling tube constituted by the second inner insulating layer 32, it is easy to manufacture the wire harness unit, for example, compared with a case where the turnback tube 40 is integrated with the first cooling tube and the second cooling tube. That is to say, a situation can be avoided where a manufacturing process for members that include the first tubular conductor 21, the second tubular conductor 31, and the like is complicated when all of the first inner insulating layer 22, the second inner insulating layer 32, and the turnback tube 40 are configured to be integrated, making it easy to manufacture the wire harness unit.

(5) The first tubular conductor 21 is a first braided member formed by braiding metal strands, and the second tubular conductor 31 is a second braided member formed by braiding metal strands, and the first tubular conductor 21 and the second tubular conductor 31 are flexible, thus making it possible to absorb dimensional tolerance of the conductive paths 11. Further, this configuration is a counter measure against swinging generated while a vehicle is travelling.

(6) The electromagnetic shield member 50 is a shielding braided member formed by braiding metal strands, and the exposed insulating portion 22b of the first inner insulating layer 22 constituting the inlet and the exposed insulating portion 32b of the second inner insulating layer 32 constituting the outlet extend through the shielding braided member, and thus both the shielding properties for suppressing radiation of electromagnetic noise originating from the conductive paths 11 to the outside and an improvement in the ease of assembly of the cooling portion can be achieved.

(7) Since the first inner insulating layer 22 that is the first cooling tube, and the second inner insulating layer 32 that is the second cooling tube extend through the grommet 63 so as to be led to the outside, degradation of the water blocking properties of the wire harness unit 10 can be suppressed.

### Variations

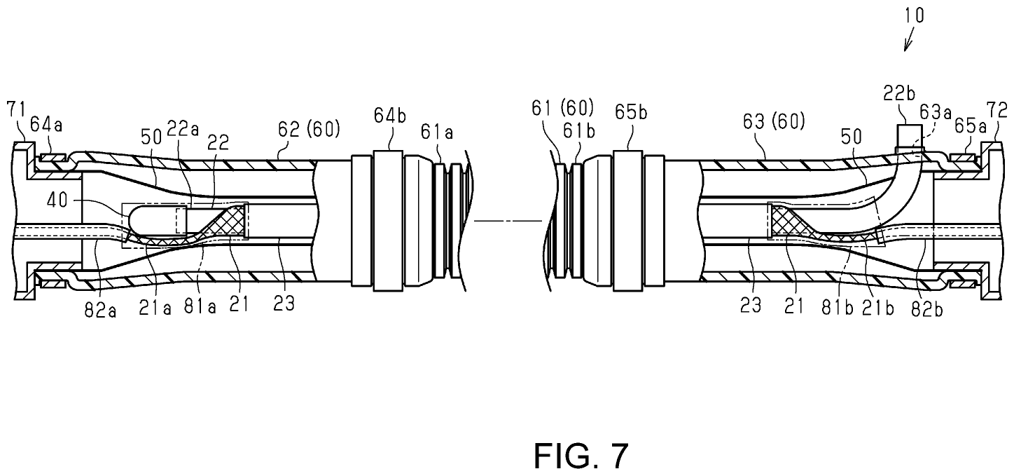

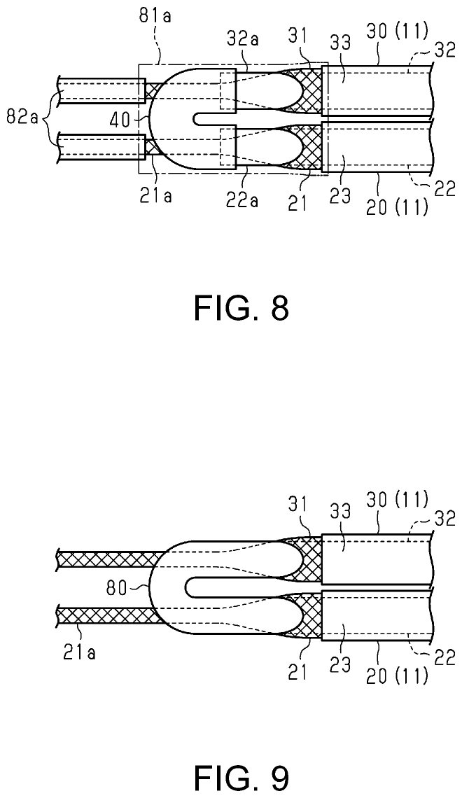

The present embodiment can be modified and implemented as follows. The present embodiment and the variations below may be implemented in combination with each other as long as no technical contradictions arise.
In the above embodiment, the number of conductive paths included in the plurality of conductive paths 11 is an even number, but there is no limitation thereto, and the number of conductive paths may be an odd number of three or more, or may be an even number of four or more. A configuration may be adopted in which, for example, the number of conductive paths 11 is three, and the cooling portion further includes a third cooling tube constituted by a third inner insulating layer of a third conductive path and a turnback tube that links the second cooling tube and the third cooling tube. Moreover, a configuration may also be adopted in which, for example, the number of conductive paths 11 is four, and the cooling portion further includes a third cooling tube, a turnback tube that links the second cooling tube and the third cooling tube, a fourth cooling tube constituted by a fourth inner insulating layer of a fourth conductive path, and a turnback tube that links the third cooling tube and the fourth cooling tube.
In the above embodiment, the turnback tube 40 is configured to be disposed inside the grommet 62, but there is no limitation thereto, and the turnback tube 40 may be configured to be disposed at another location such as inside the tubular exterior member 61.
In the above embodiment, the exposed insulating portions 22b and 32b of the first inner insulating layer 22 are led out from the grommet 63, that is, the first inner insulating layer 22 and the second inner insulating layer 32 are passed through grommet 63, but the first inner insulating layer 22 and the second inner insulating layer 32 may be led out from the connector 72. By doing so, the first tubular conductor 21, the second tubular conductor 31, and the connector 72 can be cooled.
The electromagnetic shield member 50 of the above embodiment may be a piece of metal tape or the like. An insulation layer may be provided on the inner circumferential surface of the electromagnetic shield member 50.
As shown in FIGS. 7 and 8, a configuration may be adopted in which coating members 81a and 81b that cover the exposed conductor portions 21a and 21b of the first tubular conductor 21 and the second tubular conductor 31 are provided. The coating members 81a and 81b are insulative, and prevent the exposed conductor portions 21a and 21b from coming into contact with the electromagnetic shield member 50. The coating members 81a and 81b are heat-shrinkable tubes, for example. In addition, a configuration may also be adopted in which coating members 82a and 82b that cover the exposed conductor portions 21a and 21b extending to the connectors 71 and 72 are provided. The coating members 82a and 82b are heat-shrinkable tubes, for example. Preferably, the coating members 82a and 82b respectively cover as far as the terminals 25 and 26 shown in FIG. 5.
As shown in FIG. 9, a configuration may be adopted in which a turnback tube 80 is integrated with the first cooling tube constituted by the first inner insulating layer 22 and the second cooling tube constituted by the second inner insulating layer 32. In other words, the first inner insulating layer 22, the second inner insulating layer 32, and the turnback tube 80 may be an integrally formed component. By doing so, the number of components is reduced compared with a case where they are separate.
As shown in FIGS. 3, 5, and 6, the first tubular conductor 21 according to an embodiment can have first and second length portions corresponding to the exposed conductor portions 21a at the two ends thereof, and a third length portion spanning the entire length of the first tubular conductor 21 excluding the two exposed conductor portions 21a, the third length portion being sandwiched between the outer insulating layer 23 and the first inner insulating layer 22. The first and second length portions corresponding_to the exposed conductor portions 21a do not need to be sandwiched between the outer insulating layer 23 and the first inner insulating layer 22, and may be led out from the outer insulating layer 23 and/or the first inner insulating layer 22 outward in a radial direction. If the first tubular conductor 21 is a tube made of braided wires, the exposed conductor portion 21a may be a tubular, belt-like, or linear braided wire lead formed by reducing the diameter of, transforming, or processing a tube made of braided wires that forms the first tubular conductor 21. The same applies to the second tubular conductor 31.
As shown in FIGS. 3 and 6, the wire harness unit 10 according to a preferable example can include a first metal braided conductor that is the first tubular conductor 21, a second metal braided conductor that is the second tubular conductor 31, a first cooling tube that is the first inner insulating layer 22, a second cooling tube that is the second inner insulating layer 32, the U-shaped turnback tube 40 that connects an opening end of the first cooling tube and an opening end of the second cooling tube to each other so as to form a cooling circuit, and the electromagnetic shield member 50. The first tubular insulator and the second tubular insulator each may have a first opening end, a second opening end, and a pipe length defined by the first opening end and the second opening end. The U-shaped turnback tube 40 may have a tube length that is shorter than the pipe length of each of the first tubular insulator and the second tubular insulator.
The first cooling tube that is the first inner insulating layer 22, excluding exposed insulating portions 22a and 22b at the two ends thereof, may be covered by the first tubular conductor 21, and the second cooling tube that is the second inner insulating layer 32, excluding exposed insulating portions 32a and 32b at the two ends thereof, may be covered by the second tubular conductor 31. The exposed insulating portion 22a of the first cooling tube that is the first inner insulating layer 22 and the exposed insulating portion 32a the second cooling tube that is the second inner insulating layer 32 may be covered by the electromagnetic shield member 50. The U-shaped turnback tube 40 may be covered by the electromagnetic shield member 50, but does not need to be covered by any of the first tubular conductor 21, the first inner insulating layer 22, the second tubular conductor 31, and the second inner insulating layer 32.
The two ends of the outer insulating layer 23 of the first conductive path 20 and the two ends of the outer insulating layer 33 of the second conductive path 30 may be disposed side by side. One tube end portion of the first cooling tube that is the first inner insulating layer 22 and one tube end portion of the second cooling tube that is the second inner insulating layer 32 may extend through the electromagnetic shield member 50 in a radial direction, at a predetermined length portion that is spaced far apart from first ends of the outer insulating layers 23 and 33 that are disposed side by side, and that is close to second ends of the outer insulating layers 23 and 33 that are disposed side by side.

### LIST OF REFERENCE NUMERALS

10 Wire harness unit
11 Conductive path
20 First conductive path
21 First tubular conductor (first braided member)
21a, 21b Exposed conductor portion
22 First inner insulating layer (first cooling tube)
22a, 22b Exposed insulating portion
22c Outer circumferential surface
23 Outer insulating layer
25, 26 Terminal
30 Second conductive path
31 Second tubular conductor (second braided member)
32 Second inner insulating layer (second cooling tube)
32a, 32b Exposed insulating portion
32c Outer circumferential surface
33 Outer insulating layer
40 Turnback tube
50 Electromagnetic shield member (shielding braided member)
60 Exterior member
61 Tubular exterior member
61a First end portion
61b Second end portion
62 Grommet
63 Grommet
63a Through hole
64a, 64b Fastening band
65a, 65b Fastening band
71, 72 Connector
73 Coolant
80 Turnback tube
81a, 81b Coating member
82a, 82b Coating member
M1, M2 In-vehicle device
V Vehicle

1. A wire harness unit comprising:
a plurality of conductive paths for conducting electricity between in-vehicle devices, wherein:
the plurality of conductive paths include a first conductive path and a second conductive path parallel with the first conductive path,
the first conductive path includes a first inner insulating layer formed in a hollow tube shape, and a first tubular conductor that covers an outer circumferential surface of the first inner insulating layer,
the second conductive path includes a second inner insulating layer formed in a hollow tube shape, and a second tubular conductor that covers an outer circumferential surface of the second inner insulating layer, and
a first cooling tube is formed by the first inner insulating layer through which a coolant is able to flow for cooling the plurality of conductive paths, a second cooling tube is formed by the second inner insulating layer through which the coolant is able to flow, and a turnback tube links the first cooling tube and the second cooling tube.

2. The wire harness unit according to claim 1,
wherein a number of conductive paths included in the plurality of conductive paths is an even number.

3. The wire harness unit according to claim 1, further comprising
an exterior cover for covering the conductive paths, wherein:
the exterior cover includes an exterior tube and a grommet that is connected to an end of the exterior tube, and
the turnback tube is disposed inside the grommet.

4. The wire harness unit according to claim 1,
wherein the turnback tube is separate from the first cooling tube and the second cooling tube.

5. The wire harness unit according to claim 1,
wherein the turnback tube is integrated with the first cooling tube and the second cooling tube.

6. The wire harness unit according to claim 1,
wherein the first tubular conductor is a first braided member formed by braiding metal strands, and the second tubular conductor is a second braided member formed by braiding metal strands.

7. The wire harness unit according to claim 1, further comprising
an electromagnetic shield for covering the conductive paths, wherein:
the electromagnetic shield is a shielding braided member formed by braiding metal strands,
the first inner insulating layer and the second inner insulating layer each include an exposed insulating portion that is exposed from the first tubular conductor or the second tubular conductor, and
the exposed insulating portion extends through the shielding braided member.

8. The wire harness unit according to claim 7, wherein:
the first conductive path and the second conductive path each include a terminal and an outer insulating layer that covers an outer circumferential surface of the first tubular conductor or the second tubular conductor,
the first tubular conductor and the second tubular conductor include an exposed conductor portion exposed from the outer insulating layer,
the exposed conductor portion is electrically connected to the terminal, and
the exposed conductor portion is covered by the electromagnetic shield.

9. The wire harness unit according to claim 8, further comprising
a coat for covering the exposed conductor portion.

10. The wire harness unit according to claim 1, further comprising
an exterior cover for covering the conductive paths, wherein:
the exterior cover includes an exterior tube and a grommet connected to an end of the exterior tube, and
the first inner insulating layer and the second inner insulating layer extend through the grommet.
